(19) United States
(12) Patent Application Publication
(10) Pub. No.: US 2024/0192256 A1
(43) Pub. Date: Jun. 13, 2024

(54) METHOD FOR CALCULATING OSCILLATION DAMPING RATIO OF POWER GRID

(71) Applicant: Guangxi Power Grid Electric Power Research Institute, Nanning (CN)

(72) Inventors: Yihui ZHANG, Nanning (CN); Libin WEN, Nanning (CN); Guangshi LIU, Nanning (CN); Qian DOU, Nanning (CN); Dongshan HUANG, Nanning (CN); Xiaoming WANG, Nanning (CN); Zhiyuan SUN, Nanning (CN); Guangling LU, Nanning (CN); Mingpo LI, Nanning (CN); Mosi LIU, Nanning (CN); Hao QIU, Nanning (CN); Xiaoyin QIU, Nanning (CN); Zhiyang YAO, Nanning (CN); Wei ZHANG, Nanning (CN)

(21) Appl. No.: 18/585,800

(22) Filed: Feb. 23, 2024

Related U.S. Application Data
(63) Continuation of application No. 17/753,628, filed on Mar. 9, 2022.

(51) Int. Cl. G01R 19/25; H02J 13/00

(52) U.S. Cl. CPC G01R 19/2513; H02J 13/00002

(57) ABSTRACT

The present invention disclosed a method for calculating an oscillation damping ratio of a power grid, and relates to the field of power system operation and control. When a power system oscillates, an oscillation period, two oscillation extreme points, and an oscillation direct current component start to be detected. Then an oscillation decay time constant is calculated according to the two oscillation extreme points and the oscillation direct current component. The oscillation damping ratio is calculated through the oscillation decay time constant and the oscillation period. Compared with a conventional fitting method, the conventional fitting method cannot calculate and analyze the oscillation damping ratio in a cast that a complete oscillation waveform is not obtained. The method proposed by the present inventive patent may complete the calculation of the oscillation damping ratio in a case of obtaining 2 pieces of data, so as to accelerate the speed of calculation.

### CROSS-REFERENCE TO RELATED APPLICATIONS

This application is a Continuation of the U.S. application Ser. No. 17/753,628 filed on Mar. 9, 2022, and entitled “METHOD FOR CALCULATING OSCILLATION DAMPING RATIO OF POWER GRID”, now pending, the entire disclosures of which are incorporated herein by reference.

### TECHNICAL FIELD

The present invention relates to the field of power system operation and control, and in particular, to a method for calculating an oscillation damping ratio of a power grid.

### BACKGROUND

The basis of the present invention is the calculation of the oscillation damping ratio of a power grid during operation in the prior art.

In the prior art, a fitting method is used to calculate the oscillation damping ratio of the power grid during operation. However, there are still the following requirements that cannot be met. The method in the prior art is poor in real-time performance, or, during oscillation, cannot calculate and analyze the oscillation damping ratio in a case that a complete oscillation waveform is not obtained. Therefore, a method for calculating an oscillation damping ratio of a power grid in real time during operation is required.

### SUMMARY

The present invention is intended to provide a method for calculating an oscillation damping ratio of a power grid, to resolve a current problem of poor real-time performance for calculating the oscillation damping ratio of the power grid during operation.

In order to achieve the above objective, the present invention provides a method for calculating an oscillation damping ratio of a power grid. The method includes the following steps.

At S1, when a circuit system oscillates, oscillation extreme points are detected, and an oscillation direct current component p₀ is detected.

At S2, two oscillation extreme points are selected from the oscillation extreme points.

At S3, an oscillation period of the circuit system is calculated according to the two oscillation extreme points selected in S2.

At S4, an oscillation decay time constant of the circuit system is calculated according to the two oscillation extreme points selected in S2 and the oscillation direct current component p₀.

At S5, an oscillation damping ratio is calculated according to the oscillation period and the oscillation decay time constant.

Further, the two oscillation extreme points in S2 are a first extreme point (t₁, p₁) and a second extreme point (tₙ, pₙ), where n is a sequence number of the extreme points. The oscillation period T of the circuit system calculated in S3 and a corresponding angular frequency are shown as follows.

$$T = ( {t}_{n} - {t}_{1} ) * \frac{2}{n - 1} \qquad ( 1 )$$

$$ω = 2 π \cdot \frac{1}{T} . \qquad ( 2 )$$

Further, S4 specifically includes the following steps.

At S41, values of the two oscillation extreme points with direct current components filtered out are respectively calculated.

A value p₁₀ of an extreme value of the first extreme point with the direct current component filtered out is shown as follows.

p₁₀=|p₁−p₀| (3)

A value pₙ₀ of an extreme value of the second extreme point with the direct current component filtered out is shown as follows.

pₙ₀=|pₙ−p₀| (4)

At S42, the oscillation decay time constant is calculated through the extreme values after the direct current components are filtered.

$$\frac{{p}_{10}}{{p}_{n 0}} = {e}^{σ ( {t}_{1} - {t}_{n} )} \qquad ( 5 )$$

$$σ = \frac{1}{{t}_{1} - {t}_{n}} ln ( \frac{{p}_{10}}{{p}_{n 0}} ) \qquad ( 6 )$$

In the formula (5) and the formula (6), σ is the oscillation decay time constant of the circuit system.

Further, a calculation formula of S5 for specifically calculating the oscillation damping ratio is:

$$ζ = \frac{- σ}{\sqrt{{σ}^{2} + {ω}^{2}}} .$$

The formula (1), the formula (2), the formula (3), the formula (4), and the formula (6) are put into the calculation of the oscillation damping ratio.

$$ζ = \frac{h \frac{\vert {p}_{1} - {p}_{0} \vert}{\vert {p}_{n} - {p}_{0} \vert}}{\sqrt{{( ln \frac{\vert {p}_{1} - {p}_{0} \vert}{\vert {p}_{n} - {p}_{0} \vert} )}^{2} + {{π}^{2} ( n - 1 )}^{2}}} \qquad ( 7 )$$

In the formula (7), ζ is the oscillation damping ratio.

Further, in S2, the selected two oscillation extreme points are the first two oscillation extreme points.

Compared with the prior art, the present invention has the following beneficial effects.

According to the method for calculating an oscillation damping ratio of a power grid, when the power system oscillates, the oscillation period, the two oscillation extreme points, and the oscillation direct current component start to be detected. Then the oscillation decay time constant is calculated according to the two oscillation extreme points and the oscillation direct current component. Therefore, the oscillation damping ratio is calculated through the oscillation decay time constant and the oscillation period. Compared with a conventional fitting method, the conventional fitting method cannot calculate and analyze the oscillation damping ratio in a cast that a complete oscillation waveform is not obtained. The method proposed by the present inventive patent may complete the calculation of the oscillation damping ratio in a case of obtaining 2 pieces of data, so as to accelerate the speed of calculation.

### BRIEF DESCRIPTION OF THE DRAWINGS

FIG. 1 is a flowchart of a method for calculating an oscillation damping ratio of a power grid according to the present invention.

FIG. 2 is a state oscillation curve of a power system according to an embodiment of the present invention.

### DETAILED DESCRIPTION OF THE EMBODIMENTS

The technical solutions in the present invention will be clearly and completely described below with reference to the accompanying drawings in the embodiments of the present invention. It is apparent that the described embodiments are only part of the embodiments of the present invention, not all the embodiments. Based on the embodiments in the present invention, all other embodiments obtained by those of ordinary skill in the art without creative work shall fall within the protection scope of the present invention.

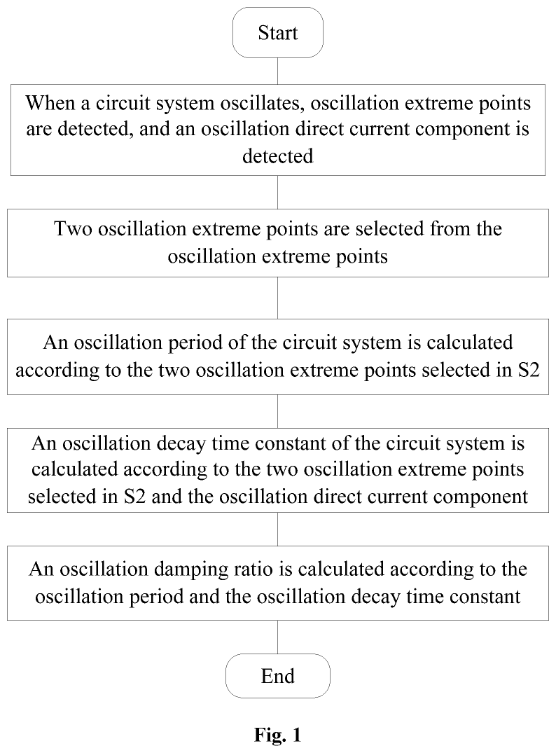

As shown in FIG. 1, a method for calculating an oscillation damping ratio of a power grid provided in the present invention includes the following steps.

At S1, when a circuit system oscillates, oscillation extreme points are detected, and an oscillation direct current component p₀ is detected.

At S2, the two oscillation extreme points selected from the oscillation extreme points respectively are a first extreme point (t₁, p₁) and a second extreme point (tₙ, pₙ), where n is a sequence number of the extreme points.

At S3, an oscillation period T of the circuit system oscillation and a corresponding angular frequency ω are calculated according to the oscillation extreme points selected in S2.

$$T = ( {t}_{n} - {t}_{1} ) * \frac{2}{n - 1} \qquad ( 1 )$$

$$ω = 2 π \cdot \frac{1}{T} . \qquad ( 2 )$$

At S4, an oscillation decay time constant of the circuit system is calculated according to the two oscillation extreme points selected in S2 and the oscillation direct current component p₀ detected in S1. S4 specifically includes the following steps.

At S41, values of the two oscillation extreme points with direct current components filtered out are respectively calculated.

A value of an extreme value of the first extreme point with the direct current component filtered out is shown as follows.

p₁₀=|p₁−p₀| (3)

A value of an extreme value of the second extreme point with the direct current component filtered out is shown as follows.

pₙ₀=|pₙ−p₀| (4)

At S42, the oscillation decay time constant σ is calculated through the extreme values after the direct current components are filtered, which is shown as follows.

$$\frac{{p}_{10}}{{p}_{n 0}} = {e}^{σ ( {t}_{1} - {t}_{n} )} \qquad ( 5 )$$

$$σ = \frac{1}{{t}_{1} - {t}_{n}} ln ( \frac{{p}_{10}}{{p}_{n 0}} ) \qquad ( 6 )$$

In the formula (5) and the formula (6), σ is the oscillation decay time constant of the circuit system.

At S5, an oscillation damping ratio is calculated according to the oscillation period and the oscillation decay time constant of the circuit system. A calculation formula of the oscillation damping ratio is

$$ζ = \frac{- σ}{\sqrt{{σ}^{2} + {ω}^{2}}} .$$

The formula (1), the formula (2), the formula (3), the formula (4), and the formula (6) are put into the calculation of the oscillation damping ratio.

$$ζ = \frac{h \frac{\vert {p}_{1} - {p}_{0} \vert}{\vert {p}_{n} - {p}_{0} \vert}}{\sqrt{{( ln \frac{\vert {p}_{1} - {p}_{0} \vert}{\vert {p}_{n} - {p}_{0} \vert} )}^{2} + {{π}^{2} ( n - 1 )}^{2}}} \qquad ( 7 )$$

In the formula (7), ζ is the oscillation damping ratio.

The embodiments of the method for calculating an oscillation damping ratio of a power grid of the present invention are described in detail, so that those skilled in the art can better understand the present invention.

At S1, after the circuit system oscillates, the oscillation extreme points start to be detected, and the oscillation direct current component p₀ is detected, p₀=1.0.

At S2, the two oscillation extreme points are selected from the oscillation extreme points. Herein, the 2 extreme points where the oscillation starts are selected, and respectively are a first extreme point (t₁, p₁) and a second extreme point (t₂, p₂).

(t₁,p₁)=(0.071,1.84).

(t₂,p₂)=(0.230,0.415).

At S3, the oscillation period T and the corresponding angular frequency ω of the circuit system is calculated according to the two oscillation extreme points selected in S2.

T=(t₂−t₁)*2=(0.230−0.071)*2=0.318

$$ω = 2 π \cdot \frac{1}{T} = 19 \text{.76} .$$

At S4, the oscillation decay time constant of the circuit system is calculated according to the two oscillation extreme points selected in S2 and the oscillation direct current component p₀ detected in S1.

The value of the extreme value of the first extreme point with the direct current component filtered out is shown as: p₁₀=|p₁−p₀|=0.84. The value of the extreme value of the second extreme point with the direct current component filtered out is shown as: pₙ₀=|pₙ−p₀|=0.585.

The oscillation decay time constant σ is calculated according to the formula (5) and the formula (6) and the extreme values after the direct current components are filtered:

$$σ = \frac{1}{0.071 - 0.23} ( ln \frac{0.84}{0.585} ) = - 2 \text{.28} .$$

At S5, the oscillation damping ratio is calculated by the oscillation period and the oscillation decay time constant of the circuit system according to the formula (7):

$$ζ = \frac{- σ}{\sqrt{{σ}^{2} + {ω}^{2}}} = \frac{2.28}{\sqrt{{2.28}^{2} + {19.76}^{2}}} = 11 \text{.4} \% .$$

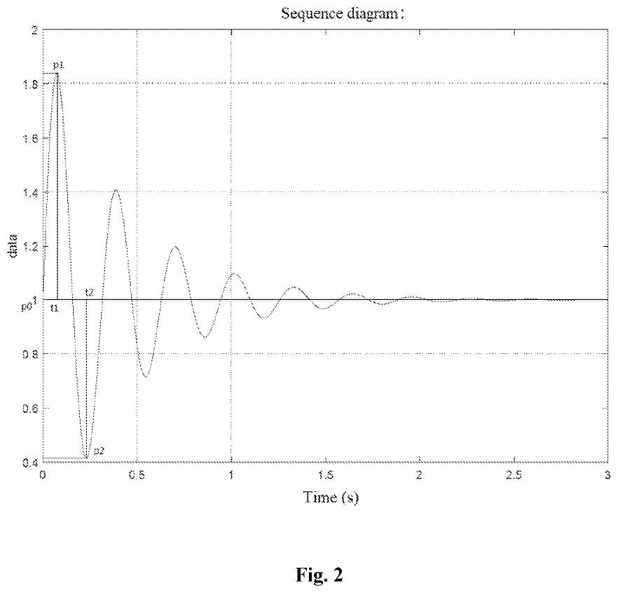

As shown in FIG. 2, FIG. 2 is a state oscillation curve of a power system. In FIG. 2, a horizontal axis is time, and a longitudinal axis is state quantity of the oscillation of the circuit system, for example, active power flowing through a circuit. It may be learned that, after a second extreme value is sampled at t₂=0.23 second by using the method for calculating an oscillation damping ratio of a power grid of the present invention, the oscillation damping ratio can be obtained through calculation. However, a conventional method needs to use a fitting method to calculate the oscillation damping ratio after the state quantity of the power system is collected with a long time, such as a 3-second waveform in FIG. 2. It may be learned that the method for calculating an oscillation damping ratio of a power grid of the present invention can rapidly calculate the oscillation damping ratio, and has a better real-time performance.

The present invention is not limited to the specific embodiments described above. The above descriptions are merely preferred examples of the disclosure, and are not intended to limit the disclosure. Any modification, equivalent replacement and improvement made within the spirit and principle of the disclosure shall be included in the protection scope of the disclosure.

What is claimed is:

1. A method for calculating an oscillation damping ratio of a power grid, comprising steps of:
S1, when a circuit system oscillates, detecting oscillation extreme points, and detecting an oscillation direct current component p₀;
S2, selecting two oscillation extreme points from the oscillation extreme points;
S3, calculating an oscillation period of the circuit system according to the two oscillation extreme points selected in S2;
S4, calculating an oscillation decay time constant of the circuit system according to the two oscillation extreme points selected in S2 and the oscillation direct current component p₀; and
S5, calculating an oscillation damping ratio according to the oscillation period and the oscillation decay time constant.

2. The method for calculating an oscillation damping ratio of a power grid as claimed in claim 1, wherein the two oscillation extreme points in S2 are a first extreme point (t₁, p₁) and a second extreme point (tₙ, pₙ), wherein n is a sequence number of the extreme points; and the oscillation period T of the circuit system calculated in S3 and a corresponding angular frequency ω are shown as:
$$T = ( {t}_{n} - {t}_{1} ) * \frac{2}{n - 1} \qquad ( 1 )$$
$$ω = 2 π \cdot \frac{1}{T} . \qquad ( 2 )$$

3. The method for calculating an oscillation damping ratio of a power grid as claimed in claim 2, wherein S4 specifically comprises steps of:
S41, respectively calculating values of the two oscillation extreme points with direct current components filtered out; and
a value p₁₀ of an extreme value of the first extreme point with the direct current component filtered out being:
p₁₀=|p₁−p₀| (3)
a value pₙ₀ of an extreme value of the second extreme point with the direct current component filtered out being:
pₙ₀=|pₙ−p₀| (4)
S42, calculating the oscillation decay time constant through the extreme values after the direct current components are filtered:
$$\frac{{p}_{10}}{{p}_{n 0}} = {e}^{σ ( {t}_{1} - {t}_{n} )} \qquad ( 5 )$$
$$σ = \frac{1}{{t}_{1} - {t}_{n}} ln ( \frac{{p}_{10}}{{p}_{n 0}} ) \qquad ( 6 )$$
wherein, in the formula (5) and the formula (6), σ is the oscillation decay time constant of the circuit system.

4. The method for calculating an oscillation damping ratio of a power grid as claimed in claim 3, wherein a calculation formula of S5 for specifically calculating the oscillation damping ratio is:
$$ζ = \frac{- σ}{\sqrt{{σ}^{2} + {ω}^{2}}} .$$
and the formula (1), the formula (2), the formula (3), the formula (4), and the formula (6) are put into the calculation of the oscillation damping ratio:
$$ζ = \frac{h \frac{\vert {p}_{1} - {p}_{0} \vert}{\vert {p}_{n} - {p}_{0} \vert}}{\sqrt{{( ln \frac{\vert {p}_{1} - {p}_{0} \vert}{\vert {p}_{n} - {p}_{0} \vert} )}^{2} + {{π}^{2} ( n - 1 )}^{2}}} \qquad ( 7 )$$
wherein, in the formula (7), ζ is the oscillation damping ratio.

5. The method for calculating an oscillation damping ratio of a power grid as claimed in claim 1, wherein, in S2, the selected two oscillation extreme points are the first two oscillation extreme points.

6. The method for calculating an oscillation damping ratio of a power grid as claimed in claim 2, wherein, in S2, the selected two oscillation extreme points are the first two oscillation extreme points.
